(19) United States
(12) Patent Application Publication
(10) Pub. No.: US 2025/0349640 A1
(43) Pub. Date: Nov. 13, 2025

(54) Semiconductor Package and Array of Semiconductor Packages

(71) Applicant: Huawei Digital Power Technologies Co., Ltd., Shenzhen (CN)

(72) Inventors: Mirko Bernardoni, Munich (DE); Lasse Petteri Palm, Nuremberg (DE); Samir Mouhoubi, Nuremberg (DE)

(73) Assignee: Huawei Digital Power Technologies Co., Ltd., Shenzhen (CN)

(21) Appl. No.: 19/244,865

(22) Filed: Jun. 20, 2025

Related U.S. Application Data
(63) Continuation of application No. PCT/EP2022/087676, filed on Dec. 23, 2022.

(51) Int. Cl. H01L 23/31; H01L 23/32; H01L 23/482; H01L 23/58; H01L 25/065

(52) U.S. Cl. CPC H01L 23/3135; H01L 23/32; H01L 23/482; H01L 23/585; H01L 25/0655; H01L 25/0657; H01L 2225/06589

(57) ABSTRACT

A semiconductor package comprises an integrated circuit comprising a first connection terminal and a second connection terminal; an encapsulant encapsulating at least part of the integrated circuit; a first metal layer and a second metal layer. The first metal layer is placed upon at least a portion of one of the side walls of the encapsulant. The first metal layer is electrically connecting the first connection terminal and is configured to form an electrically conductive and mechanically stable connection with a metal trace of a base plate when mounting the semiconductor package to the base plate. The second metal layer is placed upon at least a portion of one or both of the first main surface and the second main surface of the encapsulant.

### CROSS-REFERENCE TO RELATED APPLICATION

This is a continuation of International Patent Application No. PCT/EP2022/087676, filed on Dec. 23, 2022, which is incorporated by reference.

### TECHNICAL FIELD

The disclosure relates to the field of chip embedding and packaging technology for power packaging. In particular, the disclosure relates to a semiconductor package and an array of semiconductor packages. For example, a technology for side-plating in chip embedding is disclosed to enable modular vertical assembly of power electronics modules.

### BACKGROUND

Chip embedding technology is a new packaging technology that is nowadays used also for power packaging. A benefit of the embedding technology is that it allows reduction of parasitic inductances, maximizes electrical performance of the modules and at the same time package size is reduced.

In most packages, single side cooling prevails. Double side cooling is much more complex to be implemented. Usually one side of the package is used for electrical connection, and very often it doubles as thermal connection as well. Non-symmetrical mounting of a symmetrical package affects the balancing of the parasitic elements, in particular source inductances and gate inductances in case of parallel metal-oxide-semiconductor field-effect transistors (MOSFETs)/switches. Higher current capability products are hard to implement by modular approach based on a single building block package when symmetry of parasitic elements and thermal management are needed.

### SUMMARY

This disclosure provides a solution for overcoming the above-described problems with packaging and chip embedding technology.

The foregoing and other objects and other objectives are achieved by the features of the independent claims. Further implementation forms are apparent from the dependent claims, the description and the figures.

This disclosure presents a packaging technology that enables the build-up of modular power packages/high current output stages and also enables press-fit-like assembly techniques which are advantageous in terms of modularity and reliability. In embodiments described in this disclosure, the footprint of the package extends on the vertical side walls too, increasing the layout degrees of freedom in terms of electrical connections and thermal connections. Furthermore, also included is decoupling of planes where electrical and thermal connections are applied.

In particular, the disclosure presents a vertical package mounting solution in which side wall plating enables the mounting of the packages in a different way with respect to other example electronics assembly and packaging.

The techniques described herein can be applied to single and parallel (multiple) devices, integrated power stages/converters, e.g., buck, boost, buck/boost converters, half-bridge stages, etc. The disclosure provides a general solution that can be applied to a multitude of power electronics circuits and components.

In this disclosure, chip embedding technologies are described. There are several different types of embedding processes available: In an example chip embedding process, the electronic components (chips, capacitors, resistors, etc.) are either placed inside an opening in a printed circuit board (PCB) core layer or soldered on a two or multilayer PCB board. The actual embedding inside the final PCB board can be performed by laminating glass-reinforced epoxy laminate flame retardant material (FR4) prepregs or other polymer sheets above and below the core layer that holds the components to be embedded. The electrical connection between the embedded components and the PCB metal layers can be formed by soldering the component terminals to the inner laminate layers and subsequently laminating the PCB layers together. In more advanced embedding technologies, the components can be electrically connected by galvanically filled micro vias which is more robust, since there is no remelting of solder inside the package or board, which has to be considered when mounting the other components to the outer layers of the PCB by additional reflow processes. The micro vias are usually formed after lamination by laser drilling from the top surface through the thin laminate layer to the active chip pads or to the terminals of an embedded component package.

When using plated through holes, the inner walls of the holes are covered with a thin layer of copper, which makes the entire inner hole area conductive. This conductivity establishes an electrical connection between components and Copper (Cu) tracks. It also enhances mechanical stability and reduces the overall resistance to support smooth current flow. The average Cu plating thickness is minimum 20 micrometers (μm). As electronic components become more integrated and complex, double-sided and multi-layered PCBs were developed along with plated through-holes, so that components may connect to the desired layers, whenever required.

In this disclosure, side wall connections are described. These side wall connections can be plated and arranged on an outer surface of the package. To manufacture these side wall connections PCB processes can be used. On panel level, large plated through-holes can be mechanically drilled or oval slots can be mechanically milled along the package outline before plating/separation. After drilling/milling electroless and electrochemical plating processes can be applied to plate a metal layer, e.g., a metal layer of 20-30 μm Cu, on the through holes or the oval slots. Later, during separation of the panel into individual packages, the plated through holes or slots can be cut in half such that a section of the through hole or slot is left to one side of the cut and another section is left to the opposite size of the cut, where the cutting line defines the package outline.

According to a first aspect, the disclosure relates to a semiconductor package, comprising: at least one integrated circuit comprising at least one first connection terminal and at least one second connection terminal for an electrical connection of the at least one integrated circuit; an encapsulant encapsulating at least part of the at least one integrated circuit, the encapsulant comprising a first main surface and a second main surface opposing the first main surface and one or more side walls between the first main surface and the second main surface; a first metal layer placed upon at least a portion of one of the side walls of the encapsulant, the first metal layer being electrically connecting the at least one first connection terminal of the at least one integrated circuit and being configured to form an electrically conductive and mechanically stable connection with a metal trace of a base plate when mounting the semiconductor package to the base plate; and a second metal layer placed upon at least a portion of one or both of the first main surface and the second main surface of the encapsulant, the second metal layer electrically connecting the at least one second connection terminal of the at least one integrated circuit and forming an electrically and thermally conductive connection for a heat dissipation of the at least one integrated circuit.

Such a semiconductor package provides the technical advantage of reducing the parasitic inductances and maximizing the electrical performance of the modules and at the same time reducing the package size. The semiconductor package may be applied for double side cooling. Due to the symmetrical mounting of the package, the balancing of the parasitic elements can be optimized, in particular source inductances and gate inductances in case of parallel MOSFETs/switches can be reduced. The semiconductor package provides symmetry of parasitic elements and enables thermal management.

In an exemplary implementation of the semiconductor package, the at least one integrated circuit comprises a first main chip surface and a second main chip surface opposing the first main chip surface, the at least one integrated circuit being encapsulated in the encapsulant with both main chip surfaces being arranged parallel to the first main surface and the second main surface of the encapsulant. Thus, integrated circuits can be vertically mounted and a symmetrical double-side cooling can be implemented for the semiconductor package. The vertical direction is the direction of the vertical axis with respect to the base plate, e.g., the axis that is orthogonal to the base plate.

In an exemplary implementation of the semiconductor package, the first metal layer is placed upon a portion of one side wall, a portion of the first main surface and a portion of the second main surface, forming a C-shaped contact on three sides of the semiconductor package. Such a C-shaped contact allows an electrical contacting of the respective terminal of the integrated circuit from all three sides. A large contact area is available for contacting the respective terminal.

In an exemplary implementation of the semiconductor package, the second metal layer is placed upon a corner of the encapsulant, forming a corner metal encapsulation on four sides of the semiconductor package. Thus, the respective terminal of the integrated circuit can be electrically contacted from four sides of the semiconductor package. A large contact area is available for contacting the respective terminal enabling a flexible contacting design.

In an exemplary implementation of the semiconductor package, the second metal layer is placed upon the first main surface, the second main surface and three side walls of the encapsulant, forming a full metal encapsulation on five sides of the semiconductor package. The full metal encapsulation thus implements a large area for the current flow, e.g., of the drain terminal. Thus, high powers can be handled by such a semiconductor package.

In an exemplary implementation of the semiconductor package, the at least one integrated circuit comprises at least one third connection terminal for an electrical connection of the at least one integrated circuit; the semiconductor package further comprising: a third metal layer placed upon at least a portion of one of the side walls of the encapsulant, the third metal layer being electrically connecting the at least one third connection terminal of the at least one integrated circuit and being configured to form an electrically conductive and mechanically stable connection with a further metal trace of the base plate when mounting the semiconductor package to the base plate. Integrated circuits which have three terminals such as field-effect transistors (FETs) or insulated-gate bipolar transistors (IGBTs) can thus be included in the semiconductor package. This allows to advantageously apply the semiconductor package in a multitude of power electronics circuits and components such as an integrated power stage or converter, e.g., buck, boost, buck/boost converter, half-bridge stage, etc.

In an exemplary implementation of the semiconductor package, the third metal layer is placed upon a portion of one side wall, a portion of the first main surface and a portion of the second main surface, forming a C-shaped contact on three sides of the semiconductor package. Such a C-shaped contact allows an electrical contacting of the respective terminal of the integrated circuit from all three sides. A large contact area is available for contacting the respective terminal.

In an exemplary implementation of the semiconductor package, the semiconductor package comprises at least one second integrated circuit comprising at least one first connection terminal and at least one second connection terminal for an electrical connection of the at least one second integrated circuit; wherein the at least one integrated circuit and the at least one second integrated circuit are symmetrically arranged within the encapsulant with respect to a symmetry plane between the first main surface and the second main surface of the encapsulant. Such a configuration provides the advantage that both integrated circuits can be stacked over each other, or in a vertical arrangement of the package, placed side-by-side. This results in symmetric orientation of both integrated circuits with respect to each other, thereby allowing to reduce the influence of parasitic components in the assembly. The influence of parasitic components can be compensated because of the same line lengths due to the symmetry of the ICs.

In an exemplary implementation of the semiconductor package, the first metal layer is symmetrically placed upon a portion of the first main surface, a portion of the second main surface and a portion of one side wall of the encapsulant with respect to the symmetry plane, the first metal layer electrically connecting the at least one first connection terminal of the at least one integrated circuit and the at least one first connection terminal of the at least one second integrated circuit. This symmetrical placement allows reduction of parasitic effects in the semiconductor package due to the same line length of the first metal layer towards the connection terminals of the first integrated circuit and the second integrated circuit.

In an exemplary implementation of the semiconductor package, the semiconductor package comprises: a third metal layer and a fourth metal layer symmetrically arranged towards the symmetry plane between the at least one integrated circuit and the at least one second integrated circuit; wherein the first metal layer is electrically connecting the at least one first connection terminal of the at least one integrated circuit by at least one first electrical conductor and the third metal layer and is electrically connecting the at least one first connection terminal of the at least one second integrated circuit by at least one further first electrical conductor and the fourth metal layer, the at least one first electrical conductor and the at least one further first electrical conductor being symmetrically arranged with respect to the symmetry plane. As described above, such a symmetric arrangement provides the advantage of reducing parasitic effects of the parasitic components in the assembly.

In an exemplary implementation of the semiconductor package, the second metal layer is symmetrically placed upon a portion of the first main surface and a portion of the second main surface of the encapsulant with respect to the symmetry plane, the second metal layer electrically connecting the at least one second connection terminal of the at least one integrated circuit and the at least one second connection terminal of the at least one second integrated circuit. As described above, such a symmetric arrangement reduces parasitic effects of the parasitic components in the assembly.

In an exemplary implementation of the semiconductor package, the second metal layer is electrically connecting the at least one second connection terminal of the at least one integrated circuit by at least one second electrical conductor and is electrically connecting the at least one second connection terminal of the at least one second integrated circuit by at least one further second electrical conductor, the at least one second electrical conductor and the at least one further second electrical conductor being symmetrically arranged with respect to the symmetry plane. As described above, such a symmetric arrangement reduces parasitic effects of the parasitic components in the assembly.

According to a second aspect, the disclosure relates to an array of semiconductor packages, comprising: a plurality of semiconductor packages according to the first aspect, mounted between a first base plate and a second base plate; wherein an electrical connection of a respective semiconductor package is formed from the first base plate to the second base plate via the one or more metallized side walls of the encapsulant (150) of the respective semiconductor package; and wherein a thermally conductive connection is formed in a space between the first base plate and the second base plate via the respective first main surfaces and second main surfaces of the encapsulants of the respective semiconductor packages.

Such an array of semiconductor packages provides the technical advantage of reducing the parasitic inductances and maximizing the electrical performance of the modules and at the same time reducing the package size. The array of semiconductor packages may be applied for double side cooling. Due to the symmetrical mounting of the packages in the array, the balancing of the parasitic elements can be optimized, in particular source inductances and gate inductances in case of parallel MOSFETs/switches can be reduced. The array of semiconductor packages provides symmetry of parasitic elements and enables thermal management.

In an exemplary implementation of the array of semiconductor packages, the first metal layer of a respective semiconductor package is placed upon a portion of a side wall of the encapsulant of the respective semiconductor package opposing the first base plate; and wherein the second metal layer of a respective semiconductor package is placed upon at least a portion of both of the first main surface and the second main surface of the encapsulant of the respective semiconductor package and placed upon a portion of a side wall of the encapsulant of the respective semiconductor package opposing the second base plate. Thus, vertically stackable semiconductor packages are provided. In particular, a modular solution is offered, particularly for products with different output current ratings, for example.

In an exemplary implementation of the array of semiconductor packages, the first metal layer forms with the second metal layer of a respective semiconductor package the electrical connection of the respective semiconductor package; and wherein the second metal layers of the respective semiconductor packages form the thermally conductive connection. This provides improved thermal management since cooling can be implemented via the second metal layers and electrical connection via the first and second metal layers. For example, the large module sides can be used for thermal connection and the small module sides can be used for electrical connection of the modules.

In an exemplary implementation of the array of semiconductor packages, the plurality of semiconductor packages are releasable mounted between the first base plate and the second base plate. This provides the advantage of a modular approach, in particular, for products with different output current ratings. A solder-less “press-fit” solution can be applied.

In an exemplary implementation of the array of semiconductor packages, the array of semiconductor packages comprises: a locking element configured to mechanically lock a respective semiconductor package between the first base plate and the second base plate; wherein the locking element comprises a releasing mechanism for releasing the mechanically locking of the respective semiconductor package.

This provides the advantage of on-the-fly replacement of faulty modules by using the locking element for the locking and releasing mechanism.

### BRIEF DESCRIPTION OF THE DRAWINGS

Further embodiments of the disclosure will be described with respect to the following figures, in which:

FIG. 1 shows a 3D view of a semiconductor package 100 and an array 200 of semiconductor packages according to the disclosure.

FIG. 2 shows different views of an integrated circuit 140 included in the semiconductor package 100 of FIG. 1.

FIG. 3 shows a schematic cross section of a configuration of two integrated circuits 140, 160 included in a semiconductor package 100 according to an embodiment and two 3D views of the semiconductor package 100.

FIG. 4 shows three 3D views of a semiconductor package 100 according to an embodiment.

FIG. 5 shows three schematic cross sections of a configuration of two integrated circuits 140, 160 included in a semiconductor package 100 according to an embodiment, representing different mounting positions of the semiconductor package 100.

FIG. 6 shows four 3D views of metal layers of a semiconductor package 100 according to the disclosure representing different embodiments of metal layer shapes.

FIG. 7 shows a 3D view of a semiconductor package 100 according to an embodiment.

FIG. 8 shows a 3D view of an array of semiconductor packages 200 according to the disclosure and a cross section view of the array of semiconductor packages 200.

FIG. 9 shows a front view 900a and a cross-section longitudinal view 900b of the array of semiconductor packages 200 shown in FIG. 8.

### DETAILED DESCRIPTION

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the disclosure. The following detailed description, therefore, is not to be taken in a limiting sense, and the scope of the disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

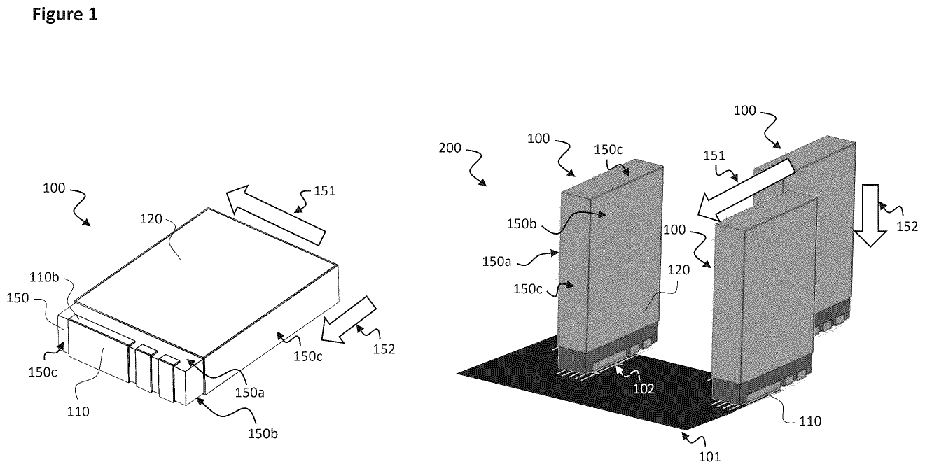

FIG. 1 shows a 3D view of a semiconductor package 100 and an array 200 of semiconductor packages according to the disclosure.

A semiconductor package 100 according to this disclosure comprises: at least one IC 140, an encapsulant 150, a first metal layer 110 and a second metal layer 120.

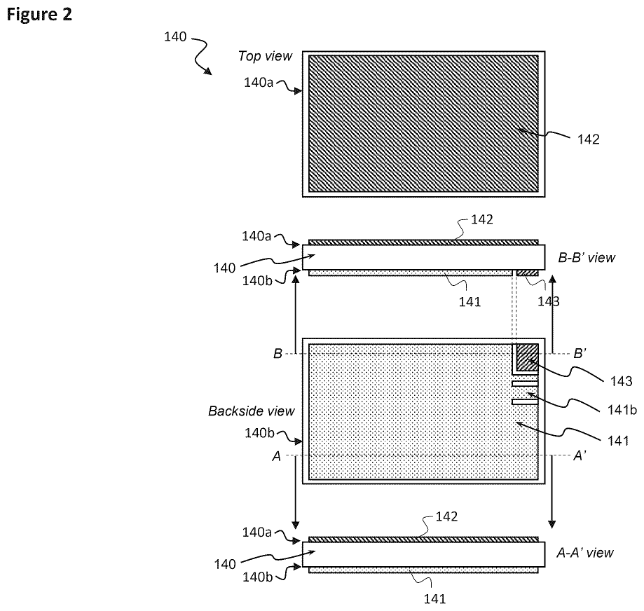

The at least one integrated circuit 140 comprises at least one first connection terminal 141 and at least one second connection terminal 142, as shown in FIG. 2, for example, for an electrical connection of the at least one integrated circuit 140.

The encapsulant 150 is encapsulating at least part of the at least one integrated circuit 140. The encapsulant 150 comprises a first main surface 150a and a second main surface 150b opposing the first main surface 150a and one or more side walls 150c between the first main surface 150a and the second main surface 150b as shown in FIG. 1.

The first metal layer 110 is placed upon at least a portion of one of the side walls 150c of the encapsulant 150. The first metal layer 110 is electrically connecting the at least one first connection terminal 141 of the at least one integrated circuit 140 and is configured to form an electrically conductive and mechanically stable connection with a metal trace 102 of a base plate 101 when mounting the semiconductor package 100 to the base plate 101.

The second metal layer 120 is placed upon at least a portion of one or both of the first main surface 150a and the second main surface 150b of the encapsulant 150. The second metal layer 120 is electrically connecting the at least one second connection terminal 142 of the at least one integrated circuit 140 and is forming an electrically and thermally conductive connection for a heat dissipation of the at least one integrated circuit 140.

The at least one integrated circuit 140 comprises a first main chip surface 140a and a second main chip surface 140b opposing the first main chip surface 140a, as shown in FIG. 2. The at least one integrated circuit 140 can be encapsulated in the encapsulant 150 with both main chip surfaces 140a, 140b being arranged parallel to the first main surface 150a and the second main surface 150b of the encapsulant 150.

The first metal layer 110 may be placed upon a portion of one side wall 150c, a portion of the first main surface 150a and a portion of the second main surface 150b, to form a C-shaped contact on three sides of the semiconductor package 100.

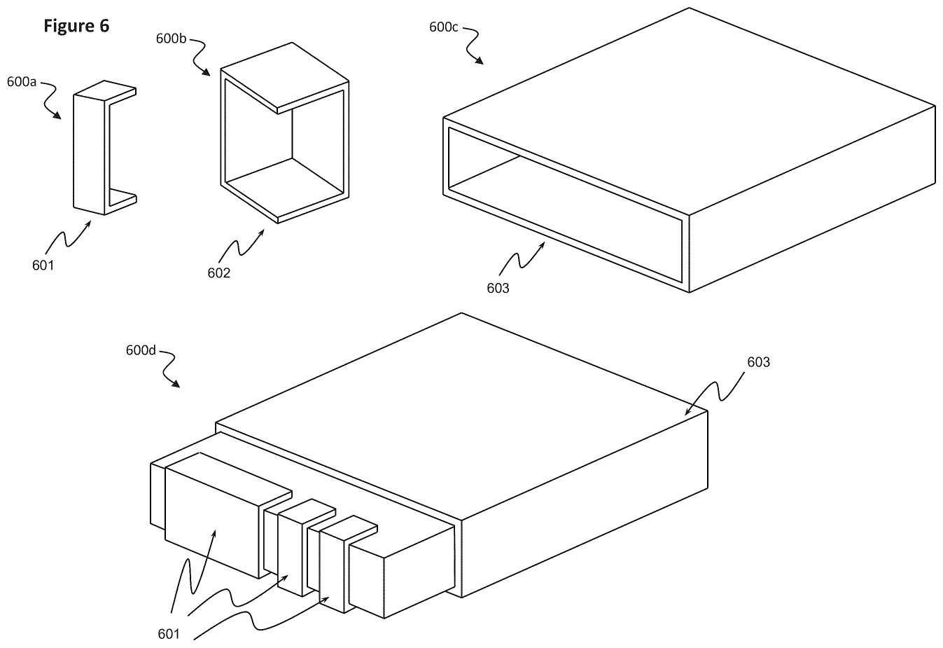

The second metal layer 120 may be placed upon a corner of the encapsulant 150, forming a corner metal encapsulation, e.g., as shown in FIG. 6, on four sides of the semiconductor package 100.

The second metal layer 120 may be placed upon the first main surface 150a, the second main surface 150b and three side walls 150c of the encapsulant 150, forming a full metal encapsulation on five sides of the semiconductor package 100, e.g., as shown in FIG. 6.

The at least one integrated circuit 140 may comprise at least one third connection terminal 143, e.g., as shown in FIG. 2, for an electrical connection of the at least one integrated circuit 140.

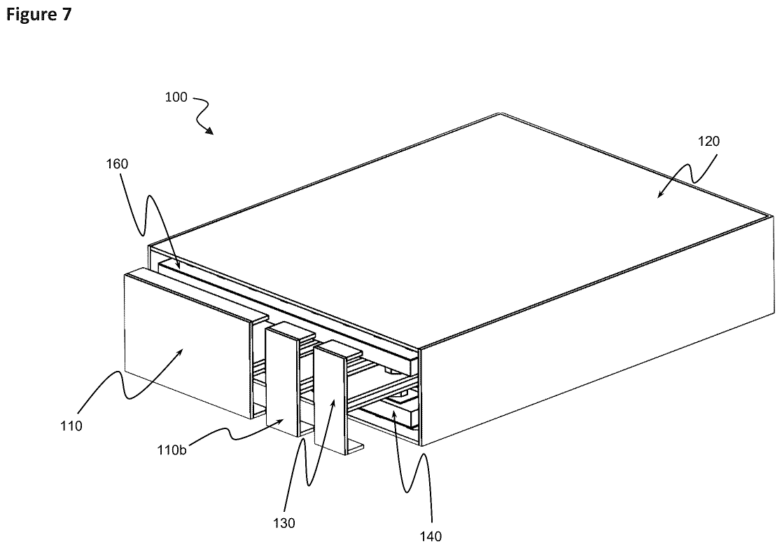

The semiconductor package 100 may further comprise: a third metal layer 130, e.g., as shown in FIG. 7, placed upon at least a portion of one of the side walls 150c of the encapsulant 150. The third metal layer 130 may electrically connect the at least one third connection terminal 143 of the at least one integrated circuit 140 and may be configured to form an electrically conductive and mechanically stable connection with a further metal trace of the base plate 101 when mounting the semiconductor package 100 to the base plate 101.

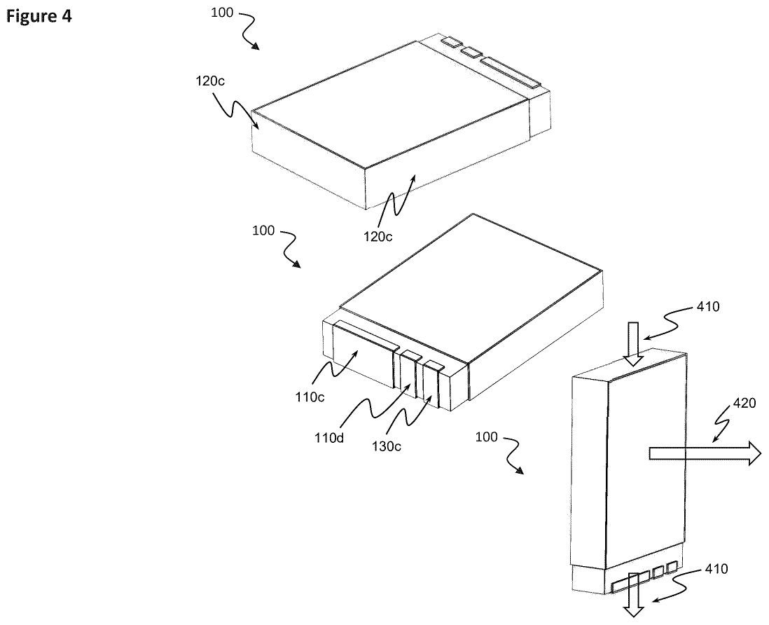

The third metal layer 130 may be placed upon a portion of one side wall 150c, a portion of the first main surface 150a and a portion of the second main surface 150b, forming a C-shaped contact on three sides of the semiconductor package 100, e.g., as shown in FIGS. 4, 6 and 7.

The semiconductor package 100 may comprise: at least one second integrated circuit 160, e.g., as shown in FIG. 2, comprising at least one first connection terminal 161 and at least one second connection terminal 162 for an electrical connection of the at least one second integrated circuit 160. The at least one integrated circuit 140 and the at least one second integrated circuit 160 may be symmetrically arranged within the encapsulant 150 with respect to a symmetry plane 301 between the first main surface 150a and the second main surface 150b of the encapsulant 150.

The first metal layer 110 may be symmetrically placed upon a portion of the first main surface 150a, a portion of the second main surface 150b and a portion of one side wall 150c of the encapsulant 150 with respect to the symmetry plane 301. The first metal layer 110 may electrically connect the at least one first connection terminal 141 of the at least one integrated circuit 140 and the at least one first connection terminal 161 of the at least one second integrated circuit 160.

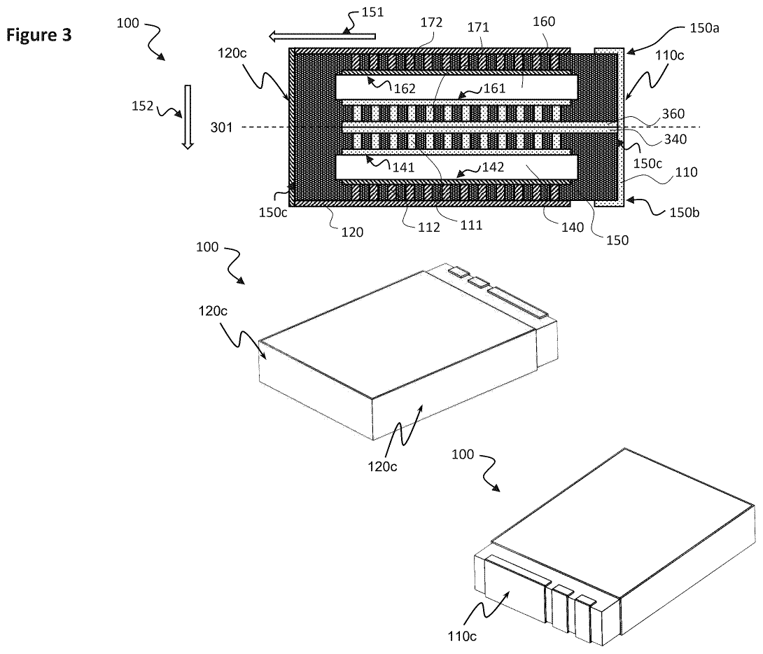

The semiconductor package 100 may comprise: a third metal layer 340 and a fourth metal layer 360, e.g., as shown in FIG. 3, symmetrically arranged towards the symmetry plane 301 between the at least one integrated circuit 140 and the at least one second integrated circuit 160. The first metal layer 110 may be electrically connecting the at least one first connection terminal 141 of the at least one integrated circuit 140 by at least one first electrical conductor 111 and the third metal layer 340, e.g., as shown in FIG. 3, and may be electrically connecting the at least one first connection terminal 161 of the at least one second integrated circuit 160 by at least one further first electrical conductor 171 and the fourth metal layer 360, e.g., as shown in FIG. 3. The at least one first electrical conductor 111 and the at least one further first electrical conductor 171 may be symmetrically arranged with respect to the symmetry plane 301, e.g., as shown in FIG. 3.

The second metal layer 120 may be symmetrically placed upon a portion of the first main surface 150a and a portion of the second main surface 150b of the encapsulant 150 with respect to the symmetry plane 301. The second metal layer 120 can electrically connect the at least one second connection terminal 142 of the at least one integrated circuit 140 and the at least one second connection terminal 162 of the at least one second integrated circuit 160.

The second metal layer 120 can electrically connect the at least one second connection terminal 142 of the at least one integrated circuit 140 by at least one second electrical conductor 112, e.g., as shown in FIG. 3, and may electrically connect the at least one second connection terminal 162 of the at least one second integrated circuit 160 by at least one further second electrical conductor 172, e.g., as shown in FIG. 3. The at least one second electrical conductor 112 and the at least one further second electrical conductor 172 can be symmetrically arranged with respect to the symmetry plane 301, e.g., as shown in FIG. 3.

FIG. 1 shows in the right-side picture an array 200 of semiconductor packages 100. This array 200 comprises: a plurality of semiconductor packages 100 as described above, mounted between a first base plate 101 and a second base plate (not shown in FIG. 1).

An electrical connection of a respective semiconductor package 100 is formed from the first base plate 101 to the second base plate via the one or more metallized side walls 150c of the encapsulant 150 of the respective semiconductor package 100. A thermally conductive connection is formed in a space between the first base plate 101 and the second base plate via the respective first main surfaces 150a and second main surfaces 150b of the encapsulants 150 of the respective semiconductor packages 100.

The first metal layer 110 of a respective semiconductor package 100 may be placed upon a portion of a side wall 150c of the encapsulant 150 of the respective semiconductor package 100 opposing the first base plate 101.

The second metal layer 120 of a respective semiconductor package 100 may be placed upon at least a portion of both of the first main surface 150a and the second main surface 150b of the encapsulant 150 of the respective semiconductor package 100 and may be placed upon a portion of a side wall 150c of the encapsulant 150 of the respective semiconductor package 100 opposing the second base plate.

The first metal layer 110 may form with the second metal layer 120 of a respective semiconductor package 100 the electrical connection of the respective semiconductor package 100. The second metal layers 120 of the respective semiconductor packages 100 may form the thermally conductive connection.

The plurality of semiconductor packages 100 can be releasable mounted between the first base plate 101 and the second base plate, e.g., by plugging the semiconductor packages 100 between both base plates or by using any other releasable connection technique.

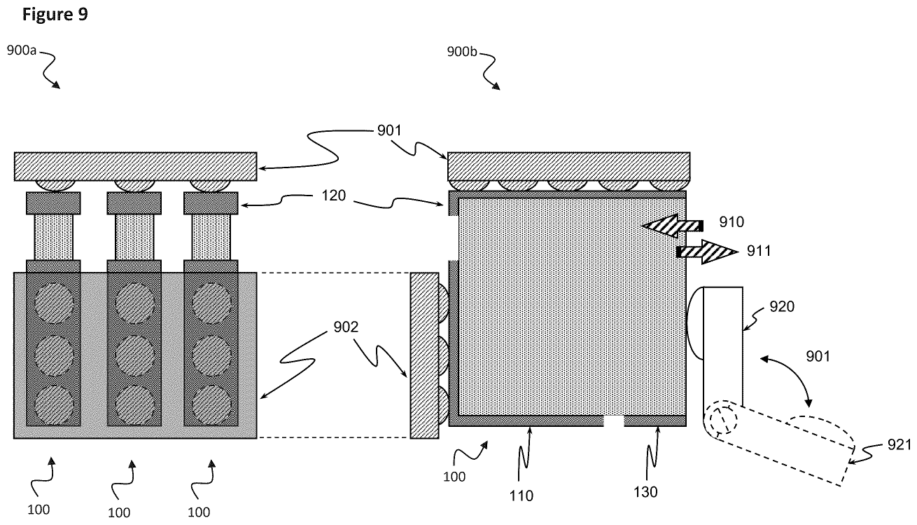

The array 200 of semiconductor packages 100 may comprise: a locking element 901, e.g., as shown in FIG. 9, configured to mechanically lock a respective semiconductor package 100 between the first base plate 101 and the second base plate. The locking element may comprise a releasing mechanism for releasing the mechanically locking of the respective semiconductor package 100.

FIG. 2 shows different views of an integrated circuit 140 included in the semiconductor package 100 of FIG. 1.

The integrated circuit 140 may correspond to the IC 140 or the IC 160 described above with respect to FIG. 1.

The integrated circuit 140 comprises a first main chip surface 140a and a second main chip surface 140b opposing the first main chip surface 140a. The first main chip surface 140a can be a top surface of the chip as shown in the top view on top of FIG. 2. The second main chip surface 140b can be a bottom surface of the chip as can be seen in the backside view of FIG. 2.

A drain pad 142 can be arranged at the first main chip surface 140a. A gate pad 143, a source pad 141 and an optional source sense pad 141b can be arranged at the second main chip surface 140b.

A cross section through the drain pad 142 is shown in the B-B′ view below the top view.

A cross section through the gate pad 143 is shown in the A-A′ view below the backside view.

As described above with respect to FIG. 1, the integrated circuit 140 can be encapsulated in the encapsulant 150 with both main chip surfaces 140a, 140b being arranged parallel to the first main surface 150a and the second main surface 150b of the encapsulant 150.

FIG. 3 shows a schematic cross section of a configuration of two integrated circuits 140, 160 included in a semiconductor package 100 according to an embodiment and two 3D views of the semiconductor package 100.

The semiconductor package 100 shown in FIG. 3 comprises a first integrated circuit 140 and a second integrated circuit 160 as described above with respect to FIG. 1.

The first integrated circuit 140 comprises at least one first connection terminal 141 and at least one second connection terminal 142 for an electrical connection of the first integrated circuit 140.

The second integrated circuit 160 comprises at least one first connection terminal 161 and at least one second connection terminal 162 for an electrical connection of the second integrated circuit 160. It understands that further ICs may be included in the package 100.

The first integrated circuit 140 and the second integrated circuit 160 are symmetrically arranged within the encapsulant 150 with respect to a symmetry plane 301 between the first main surface 150a and the second main surface 150b of the encapsulant 150.

The first metal layer 110 is symmetrically placed upon a portion of the first main surface 150a, a portion of the second main surface 150b and a portion of one side wall 150c of the encapsulant 150 with respect to the symmetry plane 301. The first metal layer 110 may electrically connect the at least one first connection terminal 141 of the first integrated circuit 140 and the at least one first connection terminal 161 of the second integrated circuit 160.

The semiconductor package 100 comprises a third metal layer 340 and a fourth metal layer 360 which are symmetrically arranged towards the symmetry plane 301 between the first integrated circuit 140 and the second integrated circuit 160. The first metal layer 110 may be electrically connecting the at least one first connection terminal 141 of the first integrated circuit 140 by at least one first electrical conductor 111 and the third metal layer 340 and may be electrically connecting the at least one first connection terminal 161 of the second integrated circuit 160 by at least one further first electrical conductor 171 and the fourth metal layer 360. The at least one first electrical conductor 111 and the at least one further first electrical conductor 171 are symmetrically arranged with respect to the symmetry plane 301.

The second metal layer 120 is symmetrically placed upon a portion of the first main surface 150a and a portion of the second main surface 150b of the encapsulant 150 with respect to the symmetry plane 301. The second metal layer 120 can electrically connect the at least one second connection terminal 142 of the first integrated circuit 140 and the at least one second connection terminal 162 of the second integrated circuit 160.

The second metal layer 120 can electrically connect the at least one second connection terminal 142 of the first integrated circuit 140 by at least one second electrical conductor 112 and may electrically connect the at least one second connection terminal 162 of the second integrated circuit 160 by at least one further second electrical conductor 172. The at least one second electrical conductor 112 and the at least one further second electrical conductor 172 are symmetrically arranged with respect to the symmetry plane 301.

FIG. 4 shows three 3D views of a semiconductor package 100 according to an embodiment.

The second metal layer 120 described above for the semiconductor package 100 can be formed as a drain vertical side wall 120c as shown in the top picture of FIG. 4.

The first metal layer 110 described above for the semiconductor package 100 can be formed as a source vertical side wall 110c as shown in the middle picture of FIG. 4. Another metal layer may form a source sense vertical side wall 110d as shown in the middle picture of FIG. 4 The third metal layer 130 described above for the semiconductor package 100 can be formed as a gate vertical side wall 130c.

According to this disclosure metallizations (metal layers) or plated surfaces on the narrow sides of the package are used to enable the vertical mounting of the package itself.

The plating on the narrow sides of the package allows to mount the package vertically, e.g., the soldering/contact happens onto the narrow sides of the package.

Arrays of vertically arranged modular power modules can be created. Connections can be laid out onto different planes. This is an advantage over standard packages where connections are always on the x-y plane.

Electrical connections 410 (with directions parallel to the current flow) and thermal connections 420 (with directions parallel to the heat flow) can be orthogonal to each other as exemplarily shown in the bottom picture of FIG. 4. An advantage thereof, e.g., when the electrical connections 410 are applied through the narrow surfaces, the wide surfaces are left available for cooling purposes (the thermal connections 420).

Connections can be considered as “encapsulations” or “rings” around the package edges.

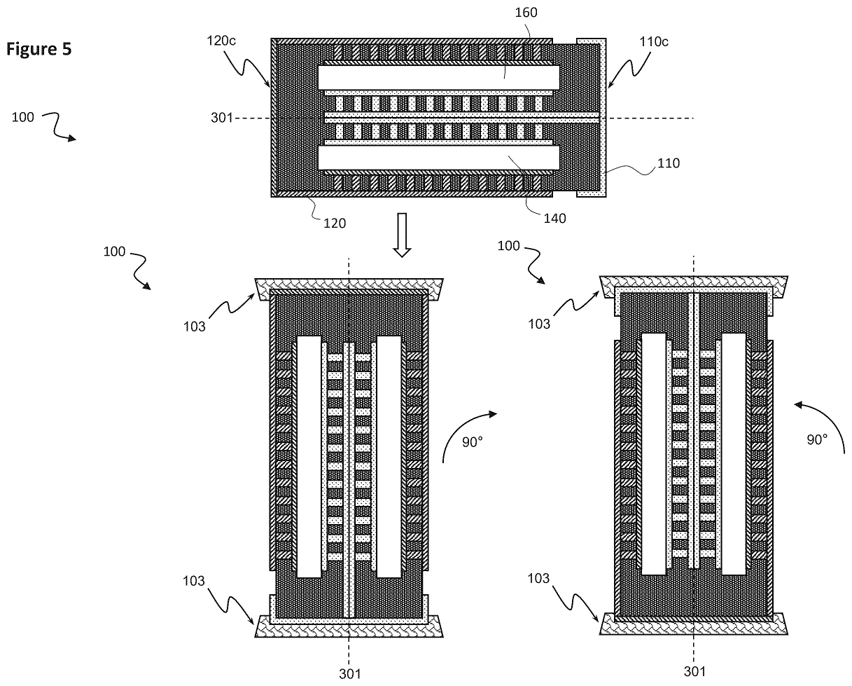

FIG. 5 shows three schematic cross sections of a configuration of two integrated circuits 140, 160 included in a semiconductor package 100 according to an embodiment, representing different mounting positions of the semiconductor package 100.

The configuration shown in FIG. 5 corresponds to the configuration shown in FIG. 3. Both integrated circuits 140, 160 are symmetrically arranged with respect to each other along a symmetry axis 301.

The semiconductor package 100 shown in the top picture of FIG. 5 can be clockwise turned by 90 degrees (see the bottom left picture) or it can be counterclockwise turned by 90 degrees (see the bottom right picture) for vertical mounting of the semiconductor package 100.

A solder layer 103 can be applied to the first metal layer 110 and the second metal layer 120 for a vertical mounting of the semiconductor package 100 between a first base plate and a second base plate to form an array of semiconductor packages 200, e.g., as shown in FIG. 1.

FIG. 6 shows four 3D views of metal layers of a semiconductor package 100 according to the disclosure representing different embodiments of metal layer shapes.

As described a above with respect to FIG. 1, the first metal layer 110 can be placed upon a portion of one side wall 150c, a portion of the first main surface 150a and a portion of the second main surface 150b, forming a C-shaped contact on three sides of the semiconductor package 100.

In the first 3D view 600a, such a C-shaped contact 601 that can be placed on three sides of the semiconductor package is shown.

As described above with respect to FIG. 1, the second metal layer 120 can be placed upon a corner of the encapsulant 150, forming a corner metal encapsulation on four sides of the semiconductor package 100.

In the second 3D view 600b, such a corner metal encapsulation 602 that can be placed on four sides of the semiconductor package is shown.

As described above with respect to FIG. 1, the second metal layer 120 can be placed upon the first main surface 150a, the second main surface 150b and three side walls 150c of the encapsulant 150, forming a full metal encapsulation on five sides of the semiconductor package 100.

In the third 3D view 600c, such a full metal encapsulation 603 that can be placed on five sides of the semiconductor package is shown.

In the fourth 3D view 600d, a semiconductor package 100 with a full metal encapsulation 603 for the drain contact and C-shaped contacts 601 for the source contact, the gate contact and the source sense contact is shown.

FIG. 7 shows a 3D view of a semiconductor package 100 according to an embodiment.

The first metal layer 110 described above for the semiconductor package 100 can be formed as a source contact for power (common) and as a vertical side wall. Another metal layer may form a source contact, sensing/Kelvin (common) 110b, also as a vertical side wall. The third metal layer 130 described above for the semiconductor package 100 can be formed as a gate contact (common) and as a vertical side wall.

Use of metallizations/plated surfaces on the narrow sides of the package enables vertical mounting of the package itself.

As an embodiment, a modified version of the die can be used where the gate contact 130 is shifted towards the edge of the chip.

For a perfectly symmetrical assembly, two specular dices 140, 160 are used as shown in FIG. 7. These dices 140, 160 may correspond to the integrated circuits 140, 160 described above with respect to FIGS. 1 to 6. The symmetrical assembly with specular dices 140, 160 can be easily achieved by chip layout. The internal routing can be designed in order to achieve the same parasitic at the gate 130 and the source 110, 110b of each device.

When the gate and source potential are brought to the devices through the contacts on the narrow surfaces, it is easy to see from FIG. 7 that the resulting parasitic elements are symmetrical, because both the mechanical assembly as well as the electrical paths are completely symmetrical.

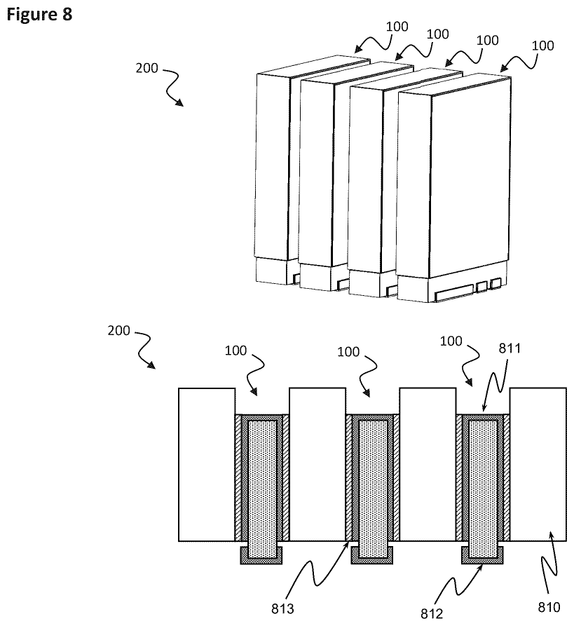

FIG. 8 shows a 3D view of an array of semiconductor packages 200 according to the disclosure and a cross section view of the array of semiconductor packages 200.

An example of the array of semiconductor packages 200 with an exemplary number of four semiconductor packages 100 is shown in FIG. 8. The semiconductor packages 100 may correspond to the semiconductor packages 100 described above with respect to FIGS. 1 to 7.

The array of semiconductor packages 200 represents a modular assembly. Modular assemblies can be assembled, with more parallel modules for higher output currents. The electrical contacts can be designed in such a way that the connection happens by mechanical contact, rather than soldering. In this case, the failure modes due to the solder joints are removed. Moreover, in case of a faulty module, it can be replaced with a functioning one by simply pulling the faulty one out, and pushing a replacement in, in an almost “on the fly” fashion.

As shown in FIG. 8, when the electrical connections are applied through the narrow surfaces, the wide surfaces are left available for cooling purposes.

Such modular vertical mounting enables efficient cooling, either through natural convection or through forced convection, liquid cooling, heat sink, etc. of all the modules 100 involved.

The cross section view on the bottom of FIG. 8 shows a comb-structure (or fin structure) which enables efficient cooling of all the finned-modules 100. Heat sinks 810 are placed between respective two modules 100, e.g., power packages 100 as described above with respect to FIGS. 1 to 7. A thermal interface material 813 may be placed between the heat sink 810 and a module 100 to improve thermal transition. A positive electrical contact 811 may be formed on the top side of each module 100 and a negative contact 812 may be formed on the bottom side of each module 100.

In one embodiment using an accurate enough mechanical process, interdigitated cooling structures can be applied by inserting the modules 100 between the cooling fins or heat sinks 810.

The array of semiconductor packages 200 thus provides the following technical advantages: a) Perfect or near-perfect symmetry of the parasitic components in the assembly; b) Achievement of a truly symmetrical double-side cooling; c) Modular approach for products with different output current ratings; d) Enabling of “press-fit” solutions (solder-less); e) Possible on-the-fly replacement of faulty modules; f) Degrees of freedom about the system connection.

FIG. 9 shows a front view 900a and a cross-section longitudinal view 900b of the array of semiconductor packages 200 shown in FIG. 8.

The figure shows an embodiment of a connection without solder for a plug-and-play modular architecture. A positive terminal 901 can be connected to the second metal layer 120, e.g., formed as a drain contact, of the semiconductor packages 100. A negative terminal 902 can be connected to the first metal layer 110, e.g., formed as a source contact, of the semiconductor packages 100. A third metal layer 130 may form a gate contact.

The modules can be inserted 910 and removed 911 as represented by the arrows 910, 911.

A locking element 901 can be configured to mechanically lock a respective semiconductor package 100 between the first base plate and the second base plate (not shown in FIG. 9). In a first position 920, the locking element can lock the respective semiconductor package 100 and in a second position 921, the respective semiconductor package 100 can be released. The locking element 901 may comprise a releasing mechanism for releasing the mechanically locking of the respective semiconductor package 100.

Besides the semiconductor package 100 described above, also a method for producing such a semiconductor package 100 is disclosed. The method comprises providing at least one integrated circuit 140 comprising at least one first connection terminal 141 and at least one second connection terminal 142 for an electrical connection of the at least one integrated circuit 140, e.g., as described above with respect to FIG. 1. The method further comprises encapsulating at least part of the at least one integrated circuit 140 by an encapsulant 150, the encapsulant 150 comprising a first main surface 150a and a second main surface 150b opposing the first main surface 150a and one or more side walls 150c between the first main surface 150a and the second main surface 150b, e.g., as described above with respect to FIG. 1. The method further comprises placing a first metal layer 110 upon at least a portion of one of the side walls 150c of the encapsulant 150, the first metal layer 110 being electrically connecting the at least one first connection terminal 141 of the at least one integrated circuit 140 and forming an electrically conductive and mechanically stable connection with a metal trace 102 of a base plate 101 when mounting the semiconductor package 100 to the base plate 101, e.g., as described above with respect to FIG. 1. The method further comprises placing a second metal layer 120 upon at least a portion of one or both of the first main surface 150a and the second main surface 150b of the encapsulant 150, the second metal layer 120 electrically connecting the at least one second connection terminal 142 of the at least one integrated circuit 140 and forming an electrically and thermally conductive connection for a heat dissipation of the at least one integrated circuit 140, e.g., as described above with respect to FIG. 1.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the disclosure. This disclosure is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the disclosure has been described with reference to one or more particular embodiments, those skilled in the art recognize that many changes may be made thereto without departing from the scope of the disclosure. It is therefore to be understood that within the scope of the appended claims and their equivalents, the disclosure may be practiced otherwise than as specifically described herein.

1. A semiconductor package, comprising:
a first integrated circuit comprising:
a first portion;
a first connection terminal configured to provide a first electrical connection for the first integrated circuit; and
a second connection terminal configured to provide a second electrical connection for the first integrated circuit;
an encapsulant encapsulating the first portion and comprising:
a first main surface comprising a second portion;
a second main surface opposite the first main surface and comprising a third portion; and
a first side wall between the first main surface and the second main surface and comprising a fourth portion;
a first metal layer located on the fourth portion, electrically connected to the first connection terminal, and configured to form an electrically conductive and mechanically stable connection; and
a second metal layer located on the second portion or the third portion or both the second portion and the third portion, electrically connected to the second connection terminal, and configured to:
form a first electrically and thermally conductive connection; and
dissipate heat from the first integrated circuit.

2. The semiconductor package of claim 1, wherein the first integrated circuit further comprises:
a first main chip surface parallel to the first main surface and the second main surface; and
a second main chip surface opposite the first main chip surface and parallel to the first main surface and the second main surface.

3. The semiconductor package of claim 1, wherein the first main surface further comprises a fifth portion, wherein the second main surface further comprises a sixth portion, and wherein the first metal layer is located on the fifth portion and the sixth portion and forms a C-shaped contact.

4. The semiconductor package of claim 1, wherein the encapsulant further comprises a corner, and wherein the second metal layer is located on the corner and form a corner metal encapsulation on four sides of the semiconductor package.

5. The semiconductor package of claim 1, wherein the encapsulant comprises:
a second side wall between the first main surface and the second main surface; and
a third side wall between the first main surface and the second main surface, and
wherein the second metal layer is located on the first main surface, the second main surface, the first side wall, the second side wall, and the third side wall and forms a full metal encapsulation of the semiconductor package.

6. The semiconductor package of claim 1, wherein the first integrated circuit comprises a third connection terminal configured to provide a third electrical connection with the first integrated circuit, wherein the first side wall further comprises a fifth portion, and wherein the semiconductor package further comprises a third metal layer located on the fifth portion, electrically connected to to the third connection terminal, and configured to form a second electrically conductive and mechanically stable connection.

7. The semiconductor package of claim 6, wherein the first main surface further comprises a sixth portion, wherein the second main surface further comprises a seventh portion, and wherein the third metal layer is located on the sixth portion and the seventh portion and forms a C-shaped contact.

8. The semiconductor package claim 1, further comprising a second integrated circuit comprising:
a third connection terminal configured to provide a third electrical connection for the second integrated circuit; and
a fourth connection terminal configured to provide a fourth electrical connection for the second integrated circuit,
wherein the first integrated circuit is a mirror image of the second integrated circuit with respect to a symmetry plane between the first main surface and the second main surface.

9. The semiconductor package of claim 8, wherein the first main surface further comprises a fifth portion, wherein the second main surface further comprises a sixth portion, and wherein the first metal layer is located on the fifth portion and the sixth portion, is reflectionally symmetric with respect to the symmetry plane, and electrically connects the first connection terminal and the third connection terminal.

10. The semiconductor package of claim 9, further comprising:
a first electrical conductor;
a second electrical conductor;
a third metal layer located between the first integrated circuit and the second integrated circuit; and
a fourth metal layer located between the first integrated circuit and the second integrated circuit,
wherein the third metal layer is a mirror image of the fourth metal layer with respect to the symmetry plane,
wherein the first metal layer is electrically connected to the first connection terminal through the first electrical conductor and the third metal layer and is electrically connected to the third connection terminal through the second electrical conductor and the fourth metal layer, and
wherein the first electrical conductor is a mirror image of the second electrical conductor with respect to the symmetry plane.

11. The semiconductor package of claim 8, wherein the first main surface further comprises a fifth portion, wherein the second main surface further comprises a sixth portion, and wherein the second metal layer is located on the fifth portion and the sixth portion, is reflectionally symmetric with respect to the symmetry plane, and electrically connects the second connection terminal and the fourth connection terminal.

12. The semiconductor package of claim 11, further comprising:
a first electrical conductor; and
a second electrical conductor,
wherein the second metal layer is electrically connected to the second connection terminal through the first electrical conductor and is electrically connected to the fourth connection terminal through the second electrical conductor, and
wherein the second electrical conductor is a mirror image of the second electrical conductor with respect to the symmetry plane.

13. An apparatus comprising:
a first base plate comprising a metal trace;
a second base plate; and
a plurality of semiconductor packages mounted between the first base plate and the second base plate, a semiconductor package of the plurality of semiconductor packages comprising:
an integrated circuit comprising:
a first portion;
a first connection terminal; and
a second connection terminal configured to provide a second electrical connection with the integrated circuit;
an encapsulant encapsulating the first portion and comprising:
a first main surface comprising a second portion;
a second main surface opposite the first main surface and comprising a third portion; and
a side wall between the first main surface and the second main surface and comprising:
metal; and
a fourth portion;
a first metal layer located on the fourth portion, electrically connected to the first connection terminal, configured to form an electrically conductive and mechanically stable connection with the metal trace when mounting the semiconductor package to the first base plate; and
a second metal layer located on the second portion or third portion or both the second portion and the third portion, electrically connected to the second connection terminal, configured to:
form an electrically and thermally conductive connection; and
dissipate heat from the integrated circuit;
wherein the first connection terminal is configured to provide a first electrical connection between the first base plate and the second base plate via the side wall, and
wherein the electrically and thermally conductive connection is formed between the first base plate and the second base plate via the first main surface and the second main surface.

14. The apparatus of claim 13, wherein the side wall further comprises:
a fifth portion; and
a sixth portion opposite the second base plate,
wherein the first main surface further comprises a seventh portion,
wherein the second main surface further comprises an eighth portion,
wherein the first metal layer is located on the fifth portion opposite the first base plate; and
wherein the second metal layer is located on the seventh portion, the eighth portion, and the sixth portion.

15. The apparatus of claim 13, wherein the first metal layer and the second metal layer further form the first electrical connection, and wherein the second metal layer further forms the electrically and thermally conductive connection.

16. The apparatus of claim 13, wherein the plurality of semiconductor packages is releasably mounted between the first base plate and the second base plate.

17. The apparatus of claim 13, further comprising a locking element configured to mechanically lock the semiconductor package between the first base plate and the second base plate and comprising a releasing mechanism configured to release the semiconductor package from between the first base plate and the second base plate.

18. An apparatus comprising:
a base plate comprising a metal trace; and
a semiconductor package comprising:
a first integrated circuit comprising:
a first portion;
a first connection terminal configured to provide a first electrical connection for the first integrated circuit; and
a second connection terminal configured to provide a second electrical connection for the first integrated circuit;
an encapsulant encapsulating the first portion and comprising:
a first main surface comprising a second portion;
a second main surface opposite the first main surface and comprising a third portion; and
a first side wall between the first main surface and the second main surface and comprising a fourth portion;
a first metal layer located on the fourth portion, electrically connected to the first connection terminal, and configured to form an electrically conductive and mechanically stable connection with the metal trace when mounting the semiconductor package to the base plate; and
a second metal layer located on the second portion or the third portion or both the second portion and the third portion, electrically connected to the second connection terminal, and configured to:
form a first electrically and thermally conductive connection; and
dissipate heat from the first integrated circuit.

19. The apparatus of claim 18, wherein the first integrated circuit further comprises:
a first main chip surface parallel to the first main surface and the second main surface; and
a second main chip surface opposite the first main chip surface and parallel to the first main surface and the second main surface.

20. The apparatus of claim 18, wherein the first main surface further comprises a fifth portion, wherein the second main surface further comprises a sixth portion, and wherein the first metal layer is located on the fifth portion and the sixth portion and forms a C-shaped contact.
